(19) United States
(12) Patent Application Publication
(10) Pub. No.: US 2008/0315888 A1
(43) Pub. Date: Dec. 25, 2008

(54) INDUCTION COIL RESISTANCE TESTER

(75) Inventors: Steven J. Ferry, Excelsior, MN (US); Marie F. Calabria, Plymouth, MN (US); Arthur J. Bertelson, Buffalo, MN (US)

Correspondence Address: SCHWEGMAN, LUNDBERG & WOESSNER, P.A., P.O. BOX 2938, MINNEAPOLIS, MN, 55402, US

(73) Assignee: NEURO VASX, Inc., North Maple Grove, MN (US)

(21) Appl. No.: 11/767,236

(22) Filed: Jun. 22, 2007

(51) Int. Cl. G01R 31/00

(52) U.S. Cl. 324/500

(57) ABSTRACT

Inventive subject matter described herein includes an induction coil resistance tester, comprising: a base effective for absorbing vibration; a mechanism for moving a sample in x, y, and z directions; a scale for measuring weight of the sample; and an ohmmeter for measuring resistance of the sample.

### FIELD

The inventive subject matter described herein relates to a device for measuring electrical resistance of a fine wire of a coil and to a method for measuring electrical resistance of a fine wire or coil.

### COPYRIGHT

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice applies to the products, processes and data as described below and in the tables that form a part of this document: Copyright 2007, Neurovasx, Inc. All Rights Reserved.

### BACKGROUND OF THE INVENTION

An aneurysm is a balloon-like swelling in a wall of a blood vessel. Aneurysms result in weakness of the vessel wall in which it occurs. This weakness predisposes the vessel to tear or rupture with potentially catastrophic consequences for any individual having the aneurysm. Vascular aneurysms are a result of an abnormal dilation of a blood vessel, usually resulting from disease and/or genetic predisposition which can weaken the arterial wall and allow it to expand. Aneurysm sites tend to be areas of mechanical stress concentration so that fluid flow seems to be the most likely initiating cause for the formation of these aneurysms.

Aneurysms in cerebral circulation tend to occur in an anterior communicating artery, posterior communicating artery, and a middle cerebral artery. The majority of these aneurysms arise from either curvature in the vessels or at bifurcations of these vessels. The majority of cerebral aneurysms occur in women. Cerebral aneurysms are most often diagnosed by the rupture and subarachnoid bleeding of the aneurysm.

Cerebral aneurysms are most commonly treated in open surgical procedures where the diseased vessel segment is clipped across the base of the aneurysm. While considered to be an effective surgical technique, particularly considering an alternative which may be a ruptured or re-bleed of a cerebral aneurysm, conventional neurosurgery suffers from a number of disadvantages. The surgical procedure is complex and requires experienced surgeons and well-equipped surgical facilities. Surgical cerebral aneurysm repair has a relatively high mortality and morbidity rate of about 2% to 10%.

Current treatment options for cerebral aneurysm fall into two categories, surgical and interventional. The surgical option has been the long held standard of care for the treatment of aneurysms. Surgical treatment involves a long, delicate operative procedure that has a significant risk and a long period of postoperative rehabilitation and critical care. Successful surgery allows for an endothelial cell to endothelial cell closure of the aneurysm and therefore a cure for the disease. If an aneurysm is present within an artery in the brain and bursts, this creates a subarachnoid hemorrhage, and a possibility that death may occur. Additionally, even with successful surgery, recovery takes several weeks and often requires a lengthy hospital stay.

In order to overcome some of these drawbacks, interventional methods and prostheses have been developed to provide an artificial structural support to the vessel region impacted by the aneurysm. The structural support must have an ability to maintain its integrity under blood pressure conditions and impact pressure within an aneurysmal sac and thus prevent or minimize a chance of rupture. U.S. Pat. No. 5,405,379 to Lane, discloses a self-expanding cylindrical tube which is intended to span an aneurysm and result in isolating the aneurysm from blood flow. While this type of stent-like device may reduce the risk of aneurysm rupture, the device does not promote healing within the aneurysm. Furthermore, the stent may increase a risk of thrombosis and embolism. Additionally, the wall thickness of the stent may undesirably reduce the fluid flow rate in a blood vessel. Stents typically are not used to treat aneurysms in a bend in an artery or in tortuous vessels such as in the brain because stents tend to straighten the vessel.

U.S. Pat. No. 5,354,295 to Guglielmi et al., describes a type of vasoclusion coil. Disadvantages of use of this type of coil are that the coil may compact, may migrate over time, and the coil does not optimize the patient's natural healing processes.

### SUMMARY OF THE INVENTION

### DESCRIPTION OF THE DRAWINGS

FIG. 1 is a side view of one embodiment of an induction coil resistance tester of the invention.

### DETAILED DESCRIPTION

Although detailed embodiments of the invention are disclosed herein, it is to be understood that the disclosed embodiments are merely exemplary of the invention that may be embodied in various and alternative forms. Specific structural and functional details disclosed herein are not to be interpreted as limiting, but merely as a basis for teaching one skilled in the art to variously employ the aneurysm filler detacher wire embodiments. Throughout the drawings, like elements are given like numerals.

Referred to herein are trade names for materials including, but not limited to, polymers and optional components. The inventors herein do not intend to be limited by materials described and referenced by a certain trade name. Equivalent materials (e.g., those obtained from a different source under a different name or catalog (reference) number to those referenced by trade name may be substituted and utilized in the methods described and claimed herein. All percentages and ratios are calculated by weight unless otherwise indicated. All percentages are calculated based on the total composition unless otherwise indicated. All component or composition levels are in reference to the active level of that component or composition, and are exclusive of impurities, for example, residual solvents or byproducts, which may be present in commercially available sources.

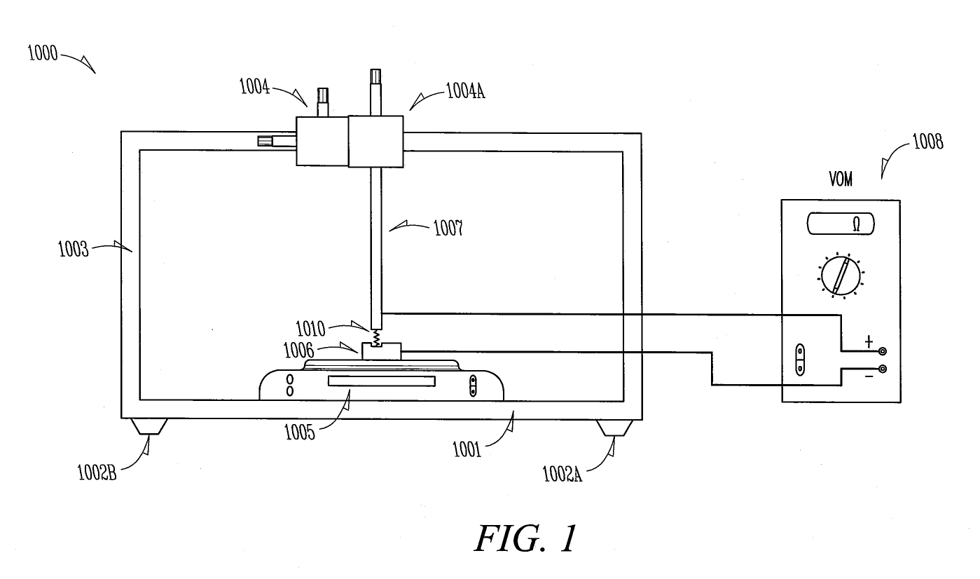

One embodiment of the invention includes a device, illustrated at 1000 in FIG. 1, for accurately measuring the electrical resistance of any fine wire coil or component. The device 1000 is usable to measure electrical resistance of fine wires or coil wire or other components that include one or more wires in devices in the medical industry, the electronics industry and other industries. The device 1000 includes a base plate 1001 and vibration feet 1002A and 1002B supporting the base plate 1001 and absorbing vibration. While two feet are shown, it is understood that the base may be supported by more than two feet, such as by four feet. The device 1000 also includes a support structure 1003 that is supported by the base plate 1001. The device 1000 also includes an x, y, z positioner 1004, and a z positioner which is shown at 1004A. The positioners 1004 and 1004A are supported by the support structure 1003.

The device 1000 also includes a weight scale 1005. For one embodiment, the weight scale 1005 included a port utilizing RSZ32 protocol, wherein bytes are sent with 8 bits, no priority stop, stop, bit, at 4800 baudrate. The weight scale 1005 is supported by the base plate 1001. The device 1000 further includes a holding fixture 1006, positioned on the weight scale 1005, which provides a support and a guide for a wire 1010, which is tested. The device 1000 also includes a probe fixture 1007, having a z-slide, and an ohm meter utilizing RS232 Port 1008. The probe fixture is used to form a contact and a circuit with the fine wire, coil or spring.

A wire or coil or spring to be tested, such as is shown at 1010, is positioned between the holding fixture 1006 and the probe fixture 1007. The device 1000 measures the induction coil resistance of very fine coils, springs or wires, such as is shown at 1010. The device 1000 is also usable to measure continuity, amperage and other electrical measurements of the very fine coils, strings or wires.

The device 1000 functions by placing the coil 1010, for example, into the holding fixture 1006. The weight scale 1005 and ohmmeter 1008 are activated. Using the x, y, z positioners, 1004 and 1004A, the probe fixture 1007 is lowered and positioned so that contact is made with the coil tip of coil 1010, forming a connection and a circuit. The connection is allowed to stabilize. When stabilized, the resistance of the coil is measured.

Another application for the device 1000 is testing the axial strength of the material and devices. For these embodiments, resistance is measured as described above and is converted to an axial strength.

For other embodiments, the device 1000 includes one or more of a horizontal iteration component, a bridge circuit and “V” blocked with one or more conductive plates.

It will be understood that the embodiments of the present invention which have been described as illustrative of some of the applications of the principles of the present invention. Various modifications may be made by those skilled in the art without departing from the spirit and scope of the invention.

1. An induction coil resistance tester, comprising:
A base effective for absorbing vibration;
A mechanism for moving a sample in x, y, and z directions;
A scale for measuring a force application to the coil; and
An ohmmeter for measuring resistance of the sample.

2. The induction coil resistance tester of claim 1, further comprising a holding mechanism for supporting the mechanism for moving the sample in the x, y, and z directions.

3. The induction coil resistance tester of claim 1, further comprising a probe fixture for probing the sample.

4. The induction coil resistance tester of claim 1, further comprising a sample holding mechanism for positioning and supporting the sample.

5. The induction coil resistance tester of claim 1, wherein the sample is one or more of a fine wire, coil, or spring.

6. The induction coil resistance tester of claim 1, further comprising a horizontal iteration component.

7. The induction coil resistance tester of claim 1, further comprising a bridge circuit.

8. The induction coil resistance tester of claim 1, further comprising a “V” blocked with one or more conductive plates.

9-12. (canceled)
